(19) United States
(12) Patent Application Publication
(10) Pub. No.: US 2003/0018846 A1
(43) Pub. Date: Jan. 23, 2003

(54) Method and system for fast memory initialization or diagnostics

(76) Inventor: Blaise Fanning, El Dorado Hills, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/908,678

(22) Filed: Jul. 18, 2001

(51) Int. Cl. G11C 5/00

(52) U.S. Cl. 711/5; 711/170; 711/104; 711/168

(57) ABSTRACT

A system with a processor and a plurality of memories. Each memory has an individual enable pins. A logic issues parallel write operations to at least one of the memories by substantially concurrent assertion of the enable pins.

### BACKGROUND OF THE INVENTION

1. Field of the Invention

The present claimed subject matter relates generally to a memory, and more specifically to an efficient operation of initializing or analyzing a memory.

2. Description of the Related Art

Traditionally, memory has been the bottleneck of computer systems. Despite a significant increase in memory capacity, memory bandwidth has only increased at a fraction of the pace of memory capacity. For example, memory capacity of a computer system has increased from thirty-two million bits (32 Mb) to two hundred fifty six (256 Mb) from 1997 to 2001, which is nearly a ten-fold increase. In contrast, memory bandwidth has increased from a rate of eight hundred million bits a second (800 Mb/sec) to approximately two giga bits a second (2 Gb/sec), which is only slight more than a two fold increase.

A computer system needs to be reset for a variety of reasons including installation of new software, reconfiguration of the system, and power up after a power shutdown. Typically, random values may be stored in the computer's system memory that result in system errors. Thus, the system basic input and output system (BIOS) firmware requests the processor to write known values into the memory to insure system reliability. However, as discussed earlier, the ten-fold increase in memory capacity while only increasing the memory bandwidth by more than two fold, will result in significant increases in initialization time of the computer system's memory.

### BRIEF DESCRIPTION OF THE SEVERAL VIEWS OF THE DRAWINGS

The subject matter regarded as the claimed subject matter is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 shows a system in accordance with one embodiment.

FIG. 2 shows a system in accordance with one embodiment.

### DETAILED DESCRIPTION OF THE INVENTION

A method and system for writing to or initializing a memory are described. In the following description, for purposes of explanation, numerous details are set forth in order to provide a thorough understanding of the present invention. However, it will be apparent to one skilled in the art that these specific details are not required in order to practice the present invention.

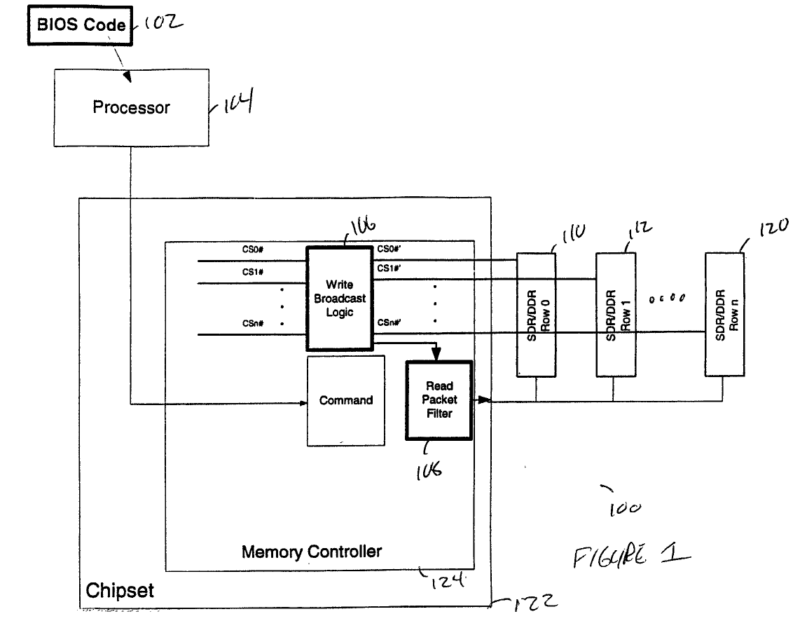

FIG. 1 illustrates a system 100 in accordance with the present invention. The system 100 comprises, but is not limited to, a basic input and output system (BIOS) firmware 102, a processor 104, a chipset 122, a memory controller 124, a write logic 106, a read packet filter 108, and a plurality of memories 110, 112, and 120.

In one embodiment, the memory controller receives a command from the BIOS 102 via the processor 104 to request an initialization or diagnostic pattern fill of the plurality of memories. The memory controller issues multiple write operations in parallel to the plurality of memories by simultaneously asserting the memories' chip select pins (CS0#′, CS1#′, etc. . . . ). The read packet filter 108 is a safeguard to prevent read operations to the memories while the memory controller has enabled parallel assertion of the chip select pins. For example, in one embodiment the read packet filter is enabled by a configuration bit, which is set by the BIOS or the processor and may be the same bit that enables parallel chip select assertion. The configuration bit causes the memory controller to convert read operations to the memory into null operations or no operations (NOPs). Thus, the null operation or no operation (NOP) does not affect the memories and prevents any destructive read operations to the memories during the write operations.

In another embodiment, the processor 104 comprises the write logic 106 and read packet filter 108 and issues the parallel write operations to the plurality of memories. In yet another embodiment, the processor 104 comprises the write logic 106 and the memories comprise the read packet filter 108.

The system 100 can be used for a variety of applications. For example, if an initialization of the memories is required, the write logic 106 can assert parallel write operations to the memories for a data type. Also, another application could be for a diagnostic analysis of the system. For example, if error-correcting code (ECC) has detected a plurality of errors that exceeds an acceptable threshold, the system 100 could perform diagnostics to determine the source of the error. The write logic can accelerate this diagnostic process by asserting parallel write operations to the memories of a data type, then either the processor 104 or the chipset 122 can perform read operations of the memories to determine the source of the error. A plurality of data types can be used to perform the parallel write operations. For example, the data type could be comprised entirely of zeroes. Alternatively, the data type could be comprised entirely of ones. Also, a data type comprised of a checkerboard pattern that is alternative zeroes and ones. Another data type is stripe data. For example, row stripes of alternative zeroes and ones. Alternatively, a data type of column stripes of zeroes and ones.

The system 100 could support a plurality of memory types. For example, the memories could be a plurality of synchronous dynamic random access memories (SDRAMs). Also, the memories could be static random access memories (SRAMS) or double data rate memories (DDR). Also, the system 100 could support different memory densities.

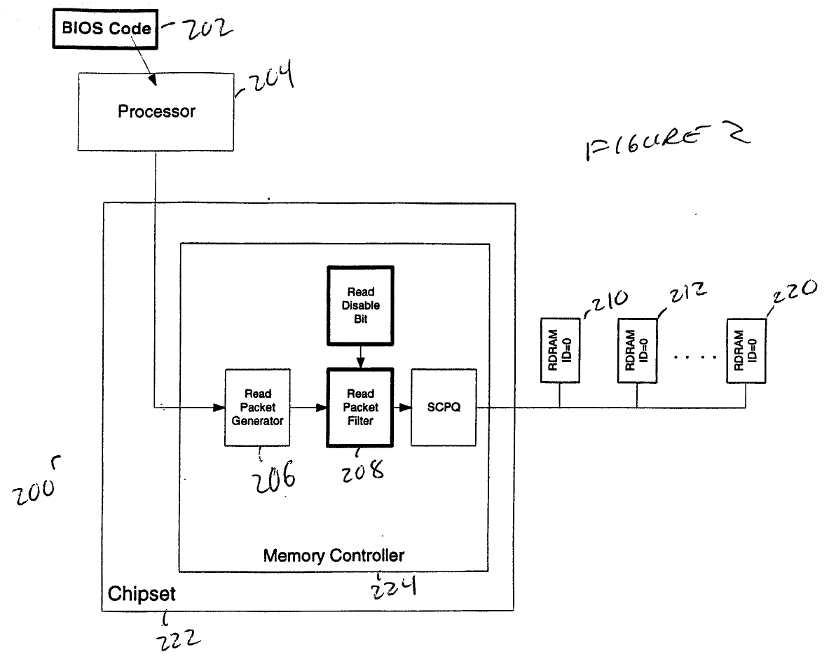

FIG. 2 illustrates a system 200 in accordance with the present invention. The system 200 comprises, but is not limited to, a basic input and output system (BIOS) firmware 202, a processor 204, a chipset 222, a memory controller 224, a read packet generator 206, a read packet filter 208, a secondary packet command queue (SPCQ) 226, and a plurality of Rambus memories (RDRAMs) 210, 212, and 220.

In one embodiment, the read packet generator of the memory controller receives a command from the BIOS 202 via the processor 204 to request an initialization or diagnostic pattern fill of the plurality of memories.

The read packet filter 208 is a safeguard to prevent read operations to the memories while the all the memories have been programmed to the same device ID. For example, in one embodiment the read packet filter is enabled by a read disable bit, which is set by the BIOS code or the processor. The read disable causes the memory controller to convert read operations entering the SPCQ 226 into null operations or no operations (NOPs). Thus, the null operation or no operation (NOP) does not affect the memories and prevents any destructive read operations to the memories during the write operations.

In another embodiment, the processor 204 comprises the read packet filter, read packet generator and SCPQ.

The system 200 can be used for a variety of applications. For example, if an initialization of the memories is required, the BIOS or processor may generate a write command with a data type. Also, another application could be for a diagnostic analysis of the system. For example, if error-correcting code (ECC) has detected a plurality of errors that exceeds an acceptable threshold, the system 200 could perform diagnostics to determine the source of the error. The system 200 can accelerate this diagnostic process by asserting parallel write operations to the memories of a data type, then either the processor 204 or the chipset 222 can perform read operations of the memories to determine the source of the error. A plurality of data types can be used to perform the parallel write operations. For example, the data type could be comprised entirely of zeroes. Alternatively, the data type could be comprised entirely of ones. Also, a data type comprised of a checkerboard pattern that is alternative zeroes and ones. Another data type is stripe data. For example, row stripes of alternative zeroes and ones. Alternatively, another data type is a plurality of column stripes of zeroes and ones.

Although the claimed subject matter has been described with reference to specific embodiments, this description is not meant to be construed in a limiting sense. Various modifications of the disclosed embodiment, as well as alternative embodiments of the invention, will become apparent to persons skilled in the art upon reference to the description of the invention. It is contemplated, therefore, that such modifications can be made without departing from the spirit or scope of the present claimed subject matter as defined in the appended claims.

[image]

1. A system comprising:
a processor;
a plurality of memories, coupled to the processor, with individual enable pins; and
a first logic, coupled to the processor and the memory, to issue a plurality of parallel write operations to at least one of the memories by substantially concurrent assertion of the enable pins.

2. The system of claim 1 further comprising a basic input and output firmware (BIOS) coupled to the processor

3. The system of claim 1 further comprising a second logic to convert a read operation to a null operation if the enable pins are concurrently asserted.

4. The system of claim 1 wherein the plurality of memories are synchronous dynamic random access memories (SDRAMs).

5. The system of claim 1 wherein the plurality of memories are static access random access memories (SRAMs).

6. The system of claim 1 wherein the plurality of memories are double data rate memories (DDRs).

7. The system of claim 1 wherein the plurality of memories are Rambus memories (RDRAMs)

8. The system of claim 1 wherein the write operations comprise a data type of a plurality of zeroes.

9. The system of claim 1 wherein the write operations comprise a data type of a plurality of ones.

10. The system of claim 1 wherein the write operations comprise a data type of one of a checkerboard, row stripes, or column stripes.

11. The system of claim 3 further comprising a memory controller to comprise the first logic and the second logic.

12. The system of claim 3 wherein the processor comprises the first logic and the second logic.

13. The system of claim 3 wherein the processor comprises the first logic and the plurality of memories comprise the second logic.

14. A method comprising:
sending a plurality of write operations of a data type to the plurality of memories;
asserting in parallel at least two enable pins of the plurality of memories; and
writing the data type to the plurality of memories.

15. The method of claim 14 further comprising initializing the plurality of memories with the data type.

16. The method of claim 14 further comprising diagnosing the plurality of memories with the data type.

17. The method of claim 14 wherein asserting in parallel each enable pin of the plurality of memories comprises converting a read operation to a null operation.

18. A system comprising:
a processor;
a plurality of memories, coupled to the processor; and
a memory controller, coupled to the processor and the memory, to issue a plurality of parallel write operations to at least one of the memories.

19. The system of claim 18 further comprising a basic input and output firmware (BIOS) coupled to the processor.

20. The system of claim 18 wherein the plurality of memories have an enable pin.

21. The system of claim 18 wherein the plurality of memories have a device identification.

22. The system of claim 18 wherein the memory controller converts a read operation to a null operation if the enable pins are concurrently asserted.

23. The system of claim 18 wherein the plurality of memories are synchronous dynamic random access memories (SDRAMs).

24. The system of claim 18 wherein the plurality of memories are static access random access memories (SRAMs).

25. The system of claim 18 wherein the plurality of memories are double data rate memories (DDRs).

26. The system of claim 18 wherein the plurality of memories are Rambus memories (RDRAMs).

27. The system of claim 18 wherein the write operations comprise a data type of a plurality of zeroes.

28. The system of claim 18 wherein the write operations comprise a data type of a plurality of ones.

29. The system of claim 18 wherein the write operations comprise a data type of one of a checkerboard, row stripes, or column stripes.
